(19) United States
(12) Patent Application Publication
(10) Pub. No.: US 2012/0119210 A1
(43) Pub. Date: May 17, 2012

(54) PIXEL STRUCTURE AND DUAL GATE PIXEL STRUCTURE

(75) Inventors: Bo-Sin Lin, Taipei County (TW); Chi-Liang Wu, Taoyuan County (TW)

(73) Assignee: CHUNGHWA PICTURE TUBES, LTD., Taoyuan (TW)

(21) Appl. No.: 13/029,133

(22) Filed: Feb. 17, 2011

(30) Foreign Application Priority Data
Nov. 16, 2010 (TW) 99139416

(51) Int. Cl. H01L 29/786

(52) U.S. Cl. 257/57; 257/E29.291

(57) ABSTRACT

A pixel structure includes a substrate, a first metal layer, a gate insulator, a semiconductor layer, a second metal layer, a passivation layer, a hole, and a pixel electrode. The first metal layer is configured on the substrate and includes a scan line, a gate, and a common electrode. The common electrode has a predetermined opening. The gate insulator covers the first metal layer. The semiconductor layer is configured on the gate insulator. The semiconductor layer underlies the entire second metal layer. The passivation layer covers the second metal layer. The hole located in the predetermined opening goes through the passivation layer and exposes the second metal layer. The pixel electrode is configured on the passivation layer and fills the hole. The pixel electrode is electrically connected to the second metal layer via the hole. A dual gate pixel structure is also provided.

### CROSS-REFERENCE TO RELATED APPLICATION

This application claims the priority benefit of Taiwan application serial no. 99139416, filed on Nov. 16, 2010. The entirety of the above-mentioned patent application is hereby incorporated by reference herein and made a part of this specification.

### BACKGROUND OF THE INVENTION

1. Field of the Invention

The invention relates to a pixel structure. More particularly, the invention relates to a pixel structure and a dual gate pixel structure of a flat panel display (FPD).

2. Description of Related Art

In the highly competitive FPD industry, manufactures are not only dedicated to research and development of FPDs with superior performance but also making great efforts to reduce production costs, so as to increase profits and supply affordable FPDs to the consumer market.

Thin film transistor liquid crystal displays (TFT LCDs), one of the most popular FPDs, are taken for example. There are various methods for reducing production costs of the TFT LCDs. One of the methods is to reduce the number of photo masks required in a fabrication process of a pixel structure, so as to reduce human power and manufacturing time and further lower down the production costs.

In general, the number of photo masks required in the fabrication process of the pixel structure can be reduced by simplifying the conventional five-mask process to be the four-mask process. FIG. 1A to FIG. 1H are schematic cross-sectional flow charts illustrating the fabrication process of a pixel structure with use of four photo masks according to the related art. With reference to FIG. 1A to FIG. 1H sequentially, in the fabrication process with use of four photo masks, a first metal layer 102 is formed on the substrate 100, and a patterning process is performed on the first metal layer 102 with use of the first photo mask. A gate insulator 104, a semiconductor layer 106, and a second metal layer 108 are sequentially formed on the entire substrate 100, and the second metal layer 108 is coated with a photoresist layer 110, as shown in FIG. 1A.

The photoresist layer 110 coated onto the second metal layer 108 is then patterned by using a half tone photo mask or a gray tone photo mask, i.e., the second photo mask 200, as shown in FIG. 1B. After the photoresist layer 110 is patterned, a first wet etching process is performed to pattern the second metal layer 108, and a first dry etching process is performed to pattern the semiconductor layer 106, as respectively shown in FIG. 1C and FIG. 1D.

The metal layer is often coated with non-uniform photoresist. For instance, the right portion of the photoresist layer 110 shown in FIG. 1A has non-uniform thickness. The relatively thin photoresist layer is likely to be completely removed after the patterning process performed on the photoresist layer, the wet etching process, the dry etching process, and the subsequently performed O₂ ashing process are implemented sequentially. As such, a portion of the underlying second metal layer 108 is exposed, as shown in FIG. 1E.

When a second wet etching process is performed with use of the photoresist layer 110 as a mask, the exposed second metal layer 108 is etched, and the underlying semiconductor layer 106 is partially exposed, as shown in FIG. 1F. A second dry etching process is then performed with use of the photoresist layer 110 as a mask, and the exposed portion of the semiconductor layer 106 is thinned out, as shown in FIG. 1G.

A passivation layer 112 is formed on the substrate 100 after the remaining photoresist layer 110 is removed, as indicated in FIG. 1G. A plurality of contact windows h1 and h2 are formed in the passivation layer 112 with use of the third photo mask, as indicated in FIG. 1H. When the contact windows h1 and h2 are formed, the first metal layer 102 and the second metal layer 108 in the other portion (not shown) of the pixel structure need to be connected via jumpers. Therefore, a portion of the semiconductor layer 106 and a portion of the gate insulator 104 that correspond to the contact window h2 are completely removed, and the first metal layer 102 that is supposed to be covered is exposed, as indicated in FIG. 1H. As such, the pixel electrode 114 formed in the last step of the four-mask process is in contact with the exposed first metal layer 102, which results in short circuit and abnormal pixel display. Accordingly, in the four-mask process, how to prevent the abnormal pixel display caused by uneven photoresist coating is one of the issues to be resolved.

### SUMMARY OF THE INVENTION

The invention is directed to a pixel structure that can preclude the abnormal pixel display.

The invention is directed to a dual gate pixel structure that can preclude the abnormal pixel display as well.

The invention provides a pixel structure that includes a substrate, a first metal layer, a gate insulator, a semiconductor layer, a second metal layer, a passivation layer, a hole, and a pixel electrode. The first metal layer is configured on the substrate. Besides, the first metal layer includes a scan line, a gate electrically connected to the scan line, and a common electrode. The common electrode is separated from the scan line and has a predetermined opening. The predetermined opening is located on an edge of the common electrode. The gate insulator is configured on the substrate and covers the first metal layer. The semiconductor layer is configured on the gate insulator. The second metal layer is configured on the semiconductor layer, and the semiconductor layer underlies the entire second metal layer. Besides, the second metal layer includes a data line, a source, a drain, and a storage electrode. The scan line and the data line are intersected. The source is electrically connected to the data line. The storage electrode is located above the predetermined opening. The passivation layer is configured on the substrate and covers the second metal layer. Besides, the passivation layer has an opening that exposes the drain. The hole located in the predetermined opening goes through the passivation layer and exposes the second metal layer. The pixel electrode is configured on the passivation layer and fills the hole. The pixel electrode is electrically connected to the drain via the opening and electrically connected to the second metal layer via the hole.

The invention further provides a dual gate pixel structure that includes a substrate, a first metal layer, a gate insulator, a semiconductor layer, a second metal layer, a passivation layer, a hole, and a pixel electrode. The first metal layer is configured on the substrate. Besides, the first metal layer includes two scan lines, two gates electrically connected to the scan lines, and a common electrode. The common electrode is separated from the scan lines and has two predetermined openings. The predetermined openings are located on an edge of the common electrode. The gate insulator is configured on the substrate and covers the first metal layer. The semiconductor layer is configured on the gate insulator. The second metal layer is configured on the semiconductor layer, and the semiconductor layer underlies the entire second metal layer. Besides, the second metal layer includes a data line, two sources, two drains, and two storage electrodes. The scan lines and the data line are intersected. The sources are electrically connected to the data line, respectively. The storage electrodes are located above the predetermined openings. The passivation layer is configured on the substrate and covers the second metal layer. Besides, the passivation layer has two openings that expose the drains. The holes located in the predetermined openings go through the passivation layer and expose the second metal layer. The pixel electrodes are configured on the passivation layer and fill the holes. The pixel electrodes are electrically connected to the drains via the openings and electrically connected to the second metal layer via the holes.

According to an embodiment of the invention, the hole that goes through the passivation layer and is located in the predetermined opening does not go through the second metal layer, the semiconductor layer, and the gate insulator.

According to an embodiment of the invention, the hole that goes through the passivation layer and is located in the predetermined opening further goes through the second metal layer, the semiconductor layer, and the gate insulator and exposes a side wall of the second metal layer, a side wall of the semiconductor layer, a side wall of the gate insulator, and a surface of the substrate.

According to an embodiment of the invention, the common electrode is located at the peripheries of the pixel electrode and is partially overlapped with the pixel electrode.

According to an embodiment of the invention, the overlapping portion of the common electrode and the pixel electrode is where a storage capacitor is formed.

According to an embodiment of the invention, an overlapping portion of the common electrode and the storage electrode is where a storage capacitor is formed.

According to an embodiment of the invention, the common electrode has at least one bending portion, and the predetermined opening and the bending portion at least have a distance therebetween.

According to an embodiment of the invention, the predetermined opening and an edge of the storage electrode at least have a distance therebetween.

According to an embodiment of the invention, the hole is substantially smaller than the predetermined opening.

In the pixel structure and the dual gate pixel structure of the invention, the predetermined opening of the common electrode can prevent a portion of the second metal layer, a portion of the semiconductor layer, and a portion of the gate insulator that are located below the hole from being etched because of the uneven photoresist coating. Further, the issue of the short circuit between the common electrode and the pixel electrode can be resolved.

In order to make the aforementioned and other features and advantages of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1A to FIG. 1H are schematic cross-sectional flow charts illustrating a fabrication process of a conventional pixel structure.

FIG. 2 is a schematic top view illustrating a pixel structure according to a first embodiment of the invention.

FIG. 3A to FIG. 3H are cross-sectional flow charts illustrating a fabrication process of a pixel structure taken along a line I-I′ depicted in FIG. 2.

FIG. 4 is a schematic top view illustrating a pixel structure according to a second embodiment of the invention.

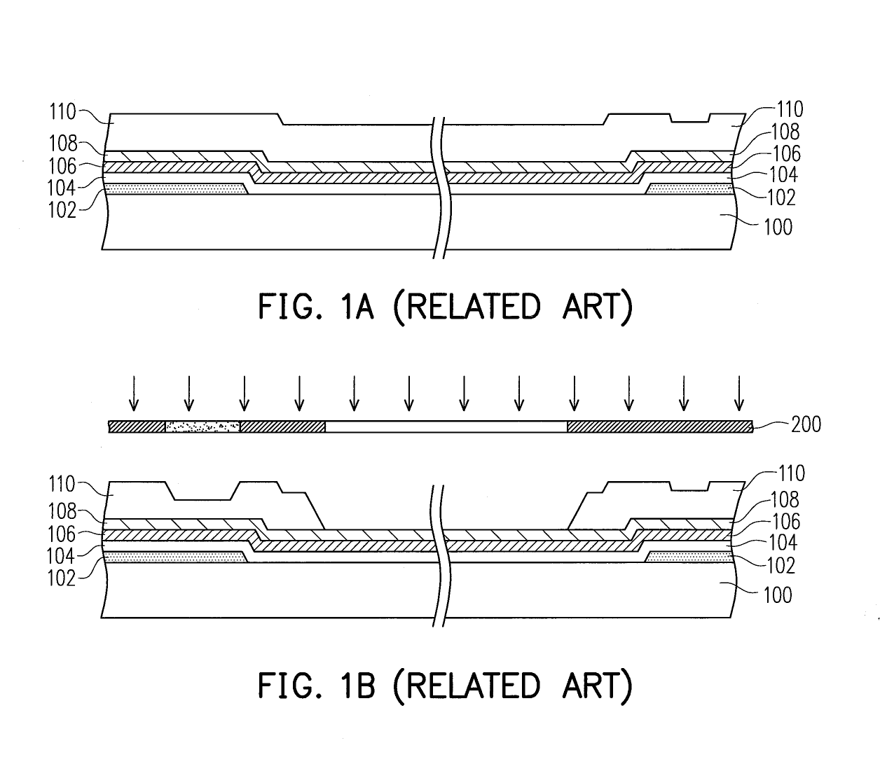

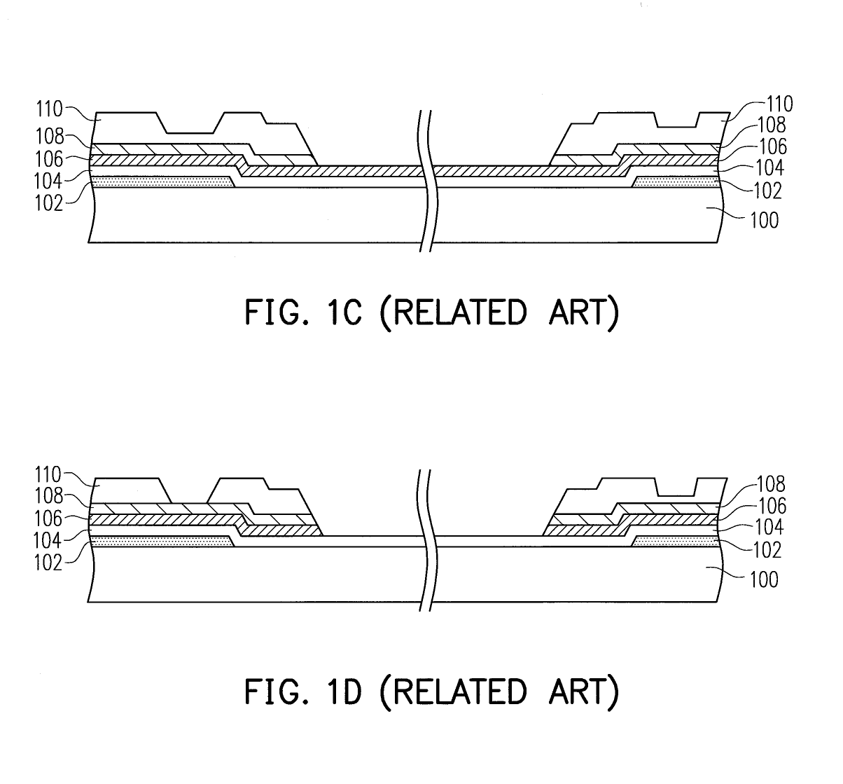

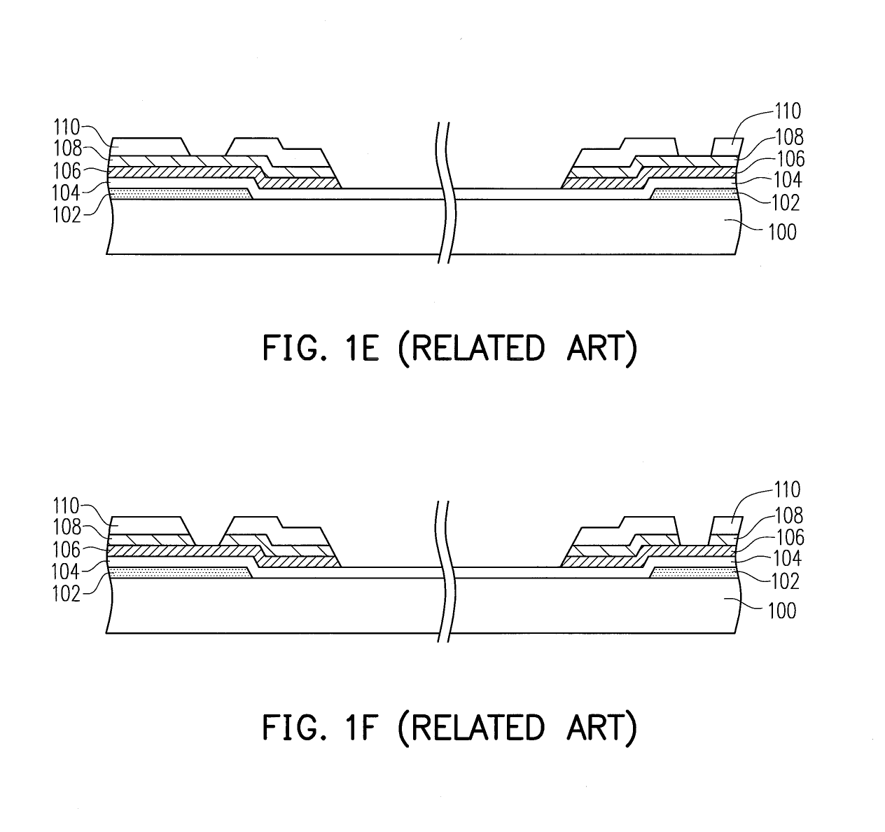

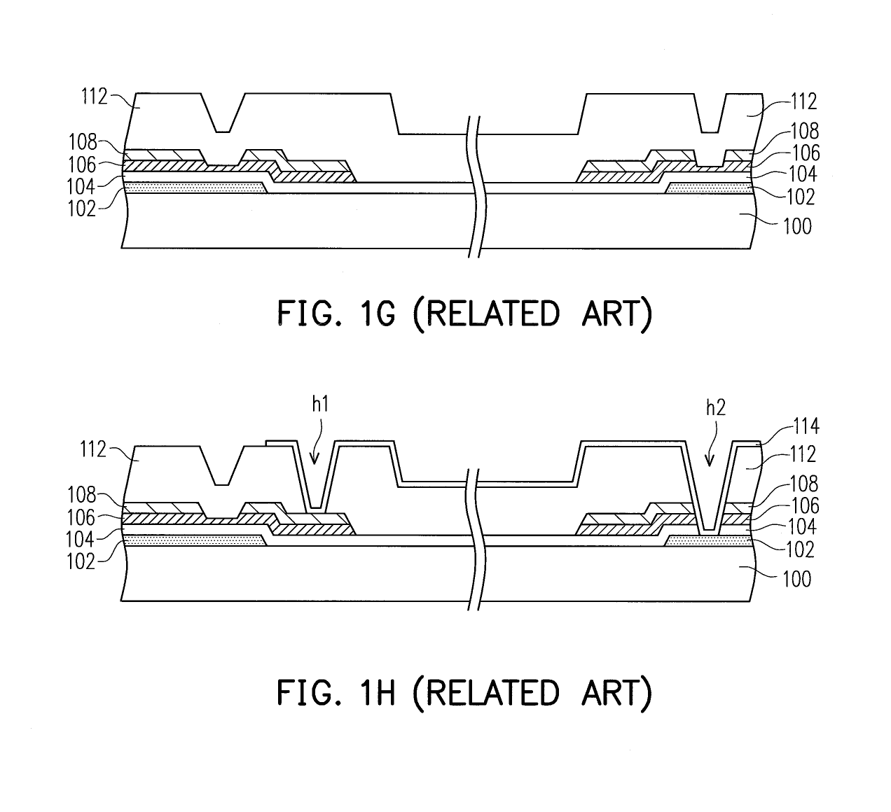

### DESCRIPTION OF EMBODIMENTS

### First Embodiment

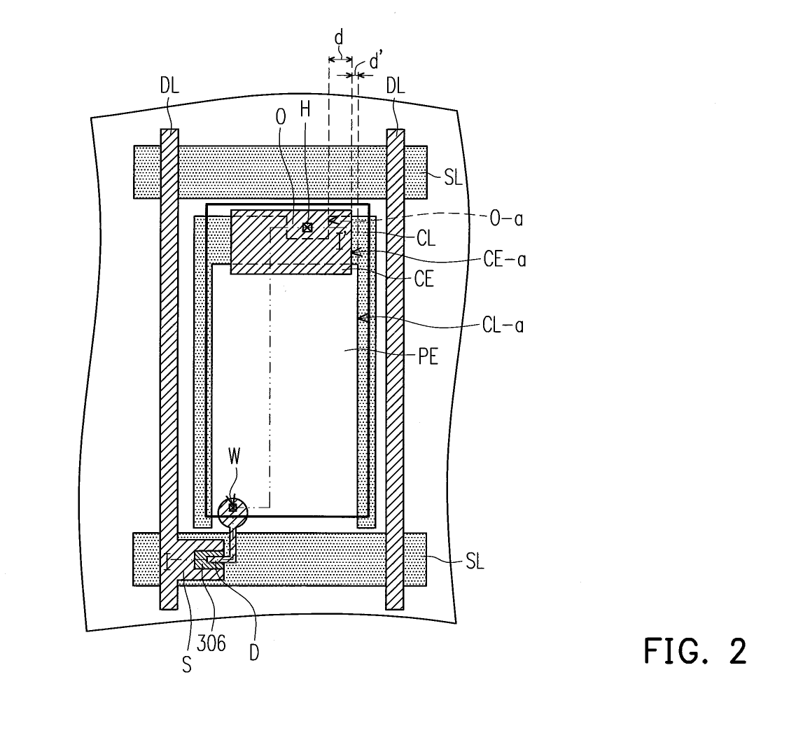

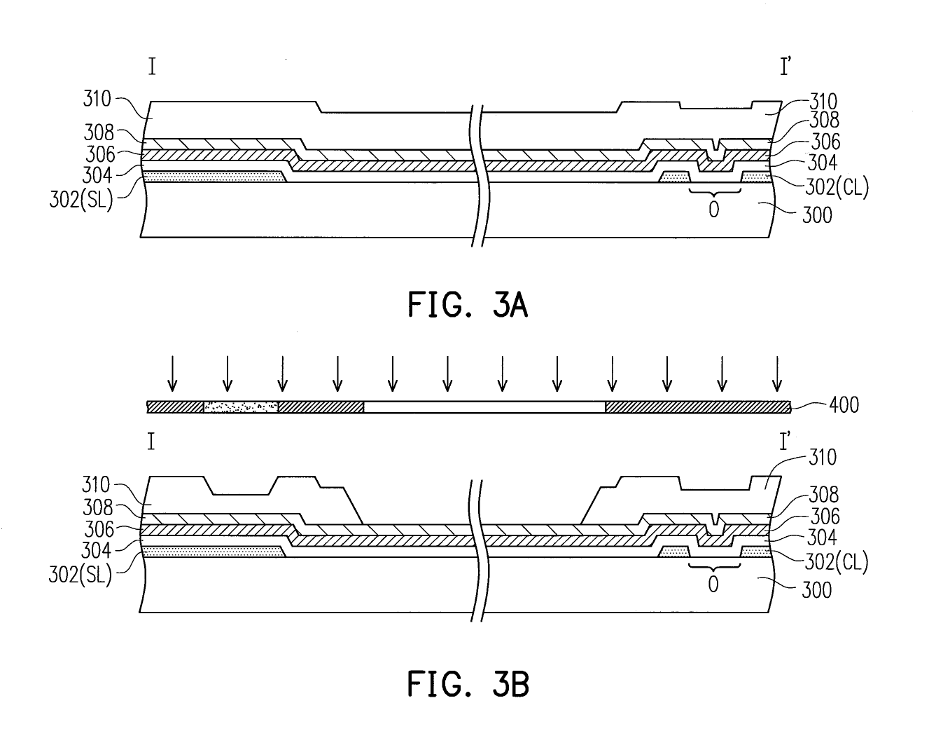

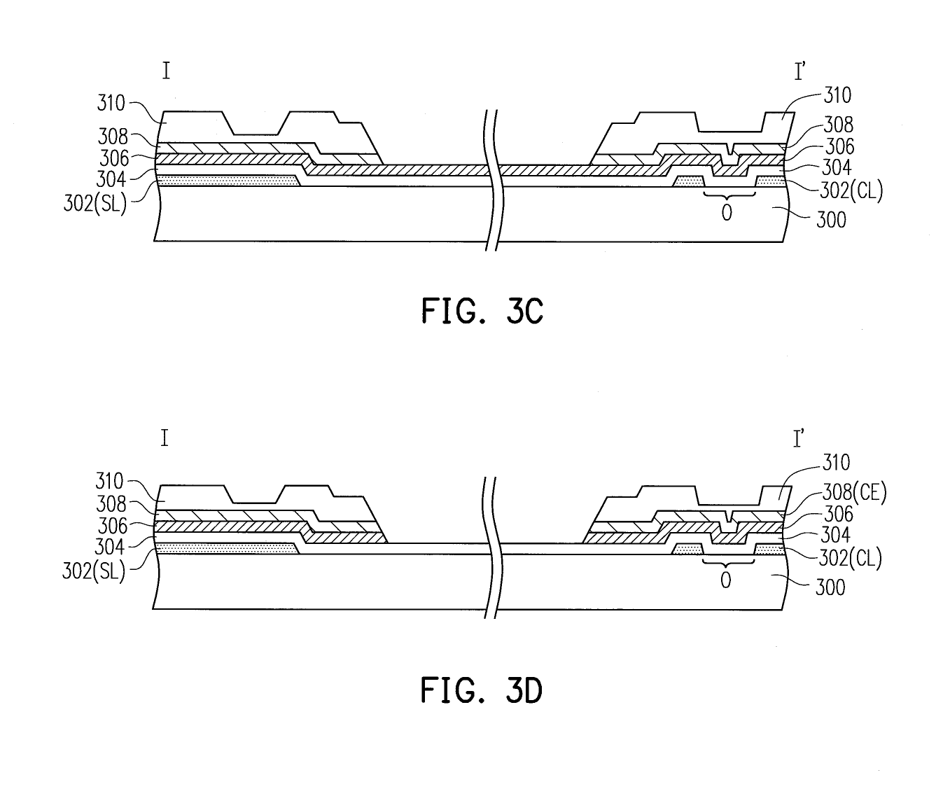

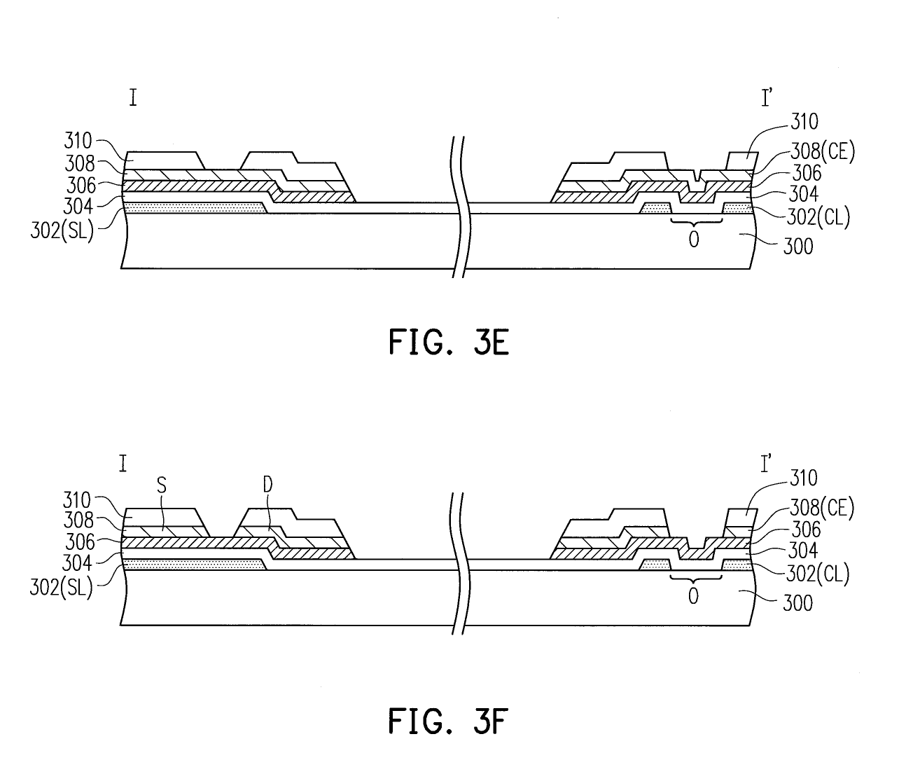

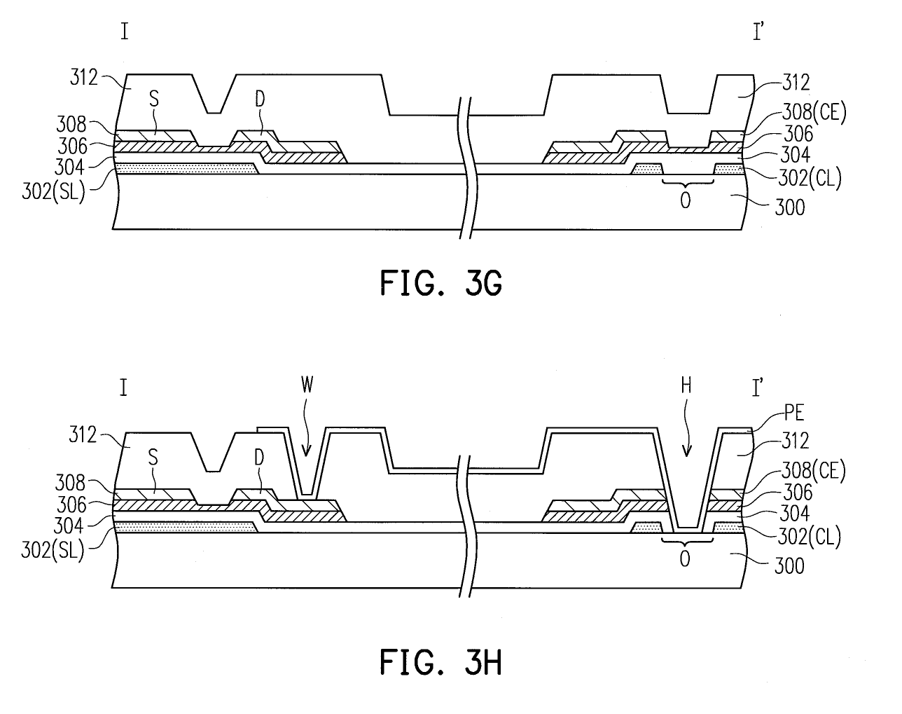

FIG. 2 is a schematic top view illustrating a pixel structure according to a first embodiment of the invention. FIG. 3A to FIG. 3H are cross-sectional flow charts illustrating a fabrication process of a pixel structure taken along a line I-I′ depicted in FIG. 2. The pixel structure and the fabrication process thereof are elaborated in this embodiment with reference to FIG. 2 and FIG. 3A to FIG. 3H.

A method of forming the pixel structure in this embodiment is exemplarily described below. As indicated in FIG. 3A, a substrate 300 is provided. A first metal layer 302 is formed on the substrate 300, and a patterning process is performed on the first metal layer 302 with use of the first photo mask. In this embodiment, the patterned first metal layer 302 includes a scan line SL and a common electrode CL separated from the scan line SL. A portion of the scan line SL serves as the gate, as indicated in FIG. 2 and FIG. 3A.

Note that the common electrode CL of this embodiment has at least one bending portion and a predetermined opening O. The predetermined opening O is located on the edge of the common electrode CL, and therefore the predetermined opening O and the bending portion have a proper distance therebetween. In this embodiment, the substrate 300 is made of glass, quartz, an organic polymer, an opaque/reflective material (e.g., a conductive material, a wafer, ceramics, or any other appropriate material), or any other appropriate material, for instance. The first metal layer 302 is made of an alloy, metal, or any other appropriate material, for instance.

A gate insulator 304, a semiconductor layer 306, and a second metal layer 308 are sequentially formed on the entire substrate 300 to cover the scan line SL and the common electrode CL. In this embodiment, the gate insulator 304 is made of an inorganic dielectric material (e.g., silicon oxide, silicon nitride, silicon oxynitride, or a stacked layer containing at least two of the aforesaid materials), an organic dielectric material, or a combination thereof, for instance. The semiconductor layer 306 of this embodiment is made of an amorphous silicon layer or any other appropriate semiconductor material, for instance. The second metal layer 308 of this embodiment is made of an alloy, metal, or any other appropriate material, for instance.

After the gate insulator 304, the semiconductor layer 306, and the second metal layer 308 are formed, the second metal layer 308 is coated with a photoresist layer 310. The photoresist layer 310 of this embodiment can be made of a positive photoresist material or a negative photoresist material, which is not limited in this invention. However, the photoresist layer 310 coated onto the second metal layer 308 often has the uneven thickness. For instance, a portion of the photoresist layer 310 that is located above the predetermined opening O has a relatively thin thickness, as indicated in FIG. 3A.

The photoresist layer 310 is then patterned with use of the second photo mask 400 (e.g., a half tone photo mask), as indicated in FIG. 3B. After the photoresist layer 310 is patterned, a first wet etching process is performed to pattern the second metal layer 308, as indicated in FIG. 3C. In addition, after the photoresist layer 310 is patterned, a first dry etching process is performed to pattern the semiconductor layer 306, as shown in FIG. 3D.

Upon completion of said processes, an O₂ ashing process is performed to clean superficial organic remains. During the O₂ ashing process, a portion of the photoresist layer 310 located above the scan line SL is removed to expose a portion of the second metal layer 308. Meanwhile, the portion of the photoresist layer 310 that is located above the predetermined opening O and has the relatively thin thickness is removed, and a portion of the underlying second metal layer 308 is exposed, as indicated in FIG. 3E.

After the photoresist layer 310 is patterned, a second wet etching process is performed to etch the exposed portion of the second metal layer 308 located above the scan line SL, such that the source S and the drain D are formed, and that a portion of the semiconductor layer 306 is exposed, as indicated in FIG. 3F. In the meantime, the exposed portion of the second metal layer 308 located above the predetermined opening O is etched to expose a portion of the semiconductor layer 306 thereunder, as indicated in FIG. 3F.

After the photoresist layer 310 is patterned, a second dry etching process is performed. Here, the exposed portion of the semiconductor layer 306 located above the scan line SL is partially removed, as indicated in FIG. 3G. The portion of the semiconductor layer 306 located above the predetermined opening O is partially removed as well, as shown in FIG. 3G. So far, all the processes performed with use of the second photo mask are completed.

Here, all the processes performed with use of the second photo mask aim at patterning the second metal layer 308 and the semiconductor layer 306. In this embodiment, the patterned second metal layer 308 includes a data line DL, the source S, the drain D, and a storage electrode CE, as indicated in FIG. 2 and FIG. 3G. With reference to FIG. 2, the data line DL and the scan line SL are intersected, and the source S and the drain D are electrically insulated from each other and cover a portion of the semiconductor layer 306 and a portion of the gate insulator 304.

Note that the pixel structure of this embodiment is formed with use of four photo masks. Namely, after the gate insulator 304, the semiconductor layer 306, and the second metal layer 308 are sequentially formed on the entire substrate 300, the gate insulator 304, the semiconductor layer 306, and the second metal layer 308 are patterned by using the same photo mask. Accordingly, after said processes are completed, the semiconductor layer 306 underlies the data line DL, the source S, the drain D, and the storage electrode CE in this embodiment. Here, the storage electrode CE of this embodiment is located above the predetermined opening O and partially overlapped with the common electrode CL. Hence, the overlapping portion of the common electrode CL and the storage electrode CE can be where a storage capacitor is formed. Besides, in this embodiment, an edge CE-a of the storage electrode CE and an edge O-a of the predetermined opening O at least have a distance d therebetween, and the edge CE-a of the storage electrode CE and an edge CL-a of the common electrode CL at least have a distance d′ therebetween. The distance d and the distance d′ are both greater than zero in this embodiment and preferably greater than the maximum error tolerance (e.g., 3 um) in an alignment process. Thus, the overlapping portion of the common electrode CL and the storage electrode CE is not varied because of the errors in the alignment process, and the storage capacitance generated thereby is not changed. As such, no relevant electrical issue caused by the changed storage capacitance is raised.

After all the processes performed with use of the second photo mask are completed, the remaining photoresist layer 310 is removed, and a passivation layer 312 is formed on the substrate 300 to cover the second metal layer 308, as shown in FIG. 3G. An opening W and a hole H are then formed in the passivation layer 312 with use of the third photo mask, as indicated in FIG. 3H.

When the opening W and the hole H are formed, note that a portion of the semiconductor layer 306 and a portion of the gate insulator 304 that correspond to the hole H are completely removed, such that the hole H which goes through the passivation layer 312 and is located in the predetermined opening O further goes through the second metal layer 308, the semiconductor layer 306, and the gate insulator 304 and exposes a side wall of the second metal layer 308, a side wall of the semiconductor layer 306, a side wall of the gate insulator 304, and a surface of the substrate 300, as indicated in FIG. 3H.

A pixel electrode PE is then formed on the substrate 300 with use of the third photo mask. The pixel electrode PE is electrically connected to the drain D via the opening W and electrically connected to the storage capacitor CE of the second metal layer 308 and the exposed substrate 300 via the hole H. Here, the conventional issue of short circuit between the pixel electrode PE and the first metal layer 302 is not raised.

The common electrode CL of this embodiment has the predetermined opening O located below the hole H, and the predetermined opening O is substantially greater in size than the hole H. In case of the uneven photoresist coating, the pixel electrode PE can merely be in contact with the storage electrode CE of the second metal layer 308 and the substrate 300 via the hole H but not in contact with the common electrode CL. Hence, the issue of short circuit is not raised. In other words, the abnormal pixel display caused by the uneven photoresist coating as disclosed in the related art can be prevented in the invention as described above, and the display quality and electrical performance of the pixel structure can be improved according to this embodiment.

It should be mentioned that the hole H going through the passivation layer 312 and located in the predetermined opening O does not go through the second metal layer 308, the semiconductor layer 306, and the gate insulator 304, given the photoresist layer 312 is evenly coated onto the second metal layer 308 and has the uniform thickness. Namely, the hole H exposes the second metal layer 308 but does not go through the second metal layer 308, nor does the hole H expose or go through the semiconductor layer 306 and the gate insulator 304.

Based on the above, another pixel structure that includes the substrate 300, the first metal layer 302, the gate insulator 304, the semiconductor layer 306, the second metal layer 308, the passivation layer 312, the hole H, and the pixel electrode PE can also be provided in this embodiment. The first metal layer 302 is configured on the substrate 300 and includes the scan line SL, the gate electrically connected to the scan line SL, and the common electrode CL. The common electrode CL is separated from the scan line SL and has a predetermined opening O that is located on the edge of the common electrode CL, as shown in FIG. 2 and FIG. 3H. The gate insulator 304 is configured on the substrate 300 and covers the first metal layer 302. The semiconductor layer 306 is configured on the gate insulator 304.

In the pixel structure of this embodiment, the second metal layer 308 is configured on the semiconductor layer 306, and the semiconductor layer 306 underlies the entire second metal layer 308. Here, the second metal layer 308 includes the data line DL, the source S, the drain D, and the storage electrode CE. The scan line SL and the data line DL are intersected. The source S is electrically connected to the data line DL. The storage electrode CE is located above the predetermined opening O. The passivation layer 312 is configured on the substrate 300 and covers the second metal layer 308. Besides, the passivation layer 312 has an opening W that exposes the drain D. In this embodiment, the hole H is located in the predetermined opening O, goes through the passivation layer 312, and exposes the second metal layer 308. The pixel electrode PE is configured on the passivation:layer 312 and fills the hole H. Here, the pixel electrode PE is electrically connected to the drain D via the opening W and electrically connected to the second metal layer 308 via the hole H.

In this embodiment, the common electrode CL of the pixel structure has the predetermined opening O located below the hole H, and the predetermined opening O is substantially greater in size than the hole H. In case of the uneven photoresist coating as described in the related art, the pixel electrode PE can merely be in contact with the storage electrode CE of the second metal layer 308 and the substrate 300 via the hole H. As such, the electrical performance of the pixel structure can be improved, and the pixel structure applied to a display device can have satisfactory display quality.

### Second Embodiment

The predetermined opening of the common electrode CL as described in the first embodiment is applicable to the dual gate pixel structure of the second embodiment, such that the issue of short circuit between the pixel electrode and the common electrode in the dual gate pixel structure of this embodiment can be prevented as well.

The method of forming the dual gate pixel structure and the material of each layer in this embodiment are similar to those described in the first embodiment, and thus no further description is provided herein. The difference between the dual gate pixel structure of this embodiment and the pixel structure of the first embodiment is elaborated hereinafter.

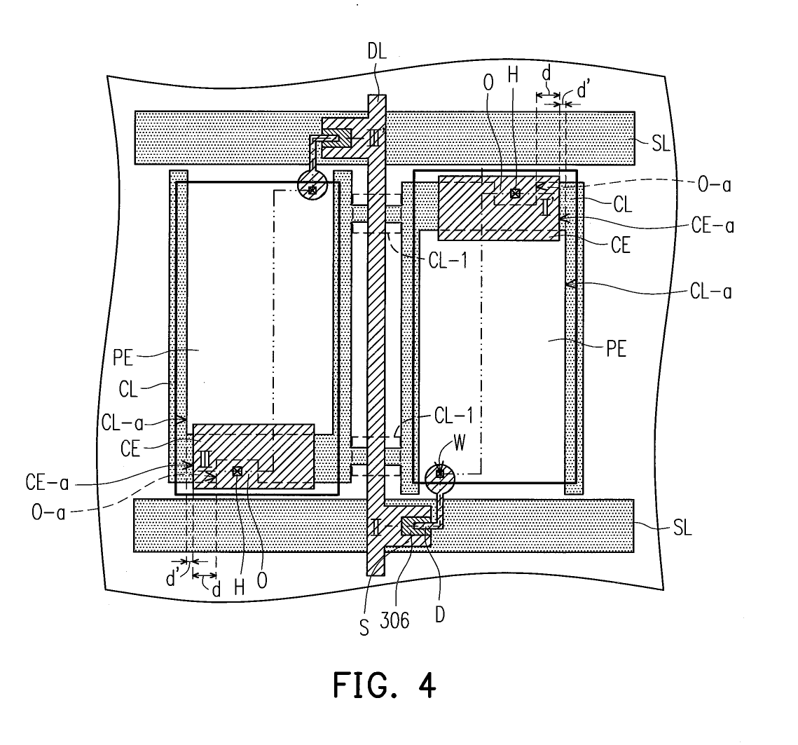

FIG. 4 is a schematic top view illustrating the dual gate pixel structure according to the second embodiment of the invention. The schematic cross-sectional view taken along the sectional lines II-II′ and III-III′ depicted in FIG. 4 is shown in FIG. 3H.

With reference to FIG. 4 and FIG. 3H, the dual gate pixel structure of this embodiment includes pixels located at the left and the right sides of the data line DL. In the dual gate pixel structure of this embodiment, the pixel located at the right side of the data line DL has the same structure as that described in the first embodiment (shown in FIG. 2). The pixel located at the right side of the data line DL is mirrored with respect to an extension direction of the scan line SL and then mirrored with respect to an extension direction of the data line DL, so as to form the pixel located at the left side of the data line DL in the dual gate pixel structure of this embodiment. Note that the pixels located at the right and the left sides of the data line DL share the same data line DL in the dual gate pixel structure of this embodiment, and the common electrodes CL of the pixels located at the right and the left sides of the data line DL are electrically connected through the connection portion CL-1 located in the same layer, as shown in FIG. 4.

Since the pixels located at the right and the left sides of the data line DL share the same data line DL in the dual gate pixel structure of this embodiment, the number of the data line DL in the pixel structure can be reduced, the number of the integrated circuits required by the display panel of the dual gate pixel structure can be decreased, and the manufacturing costs can be lowered down.

However, the storage capacitances at the right and the left sides of the data line DL in the dual gate pixel structure of this embodiment may differ from each other because the first metal layer 302 (the common electrode CL) and the second metal layer 308 (the storage electrode CE) are misaligned. As such, the display panel having said pixel structure is likely to have unfavorable display quality.

To resolve said issue, the edges CE-a of the storage electrodes CE at the right and the left sides of the data line DL and the edges O-a of the corresponding predetermined openings O have at least a distance d therebetween in the dual gate pixel structure of this embodiment. The edges CE-a of the storage electrodes CE at the right and the left sides of the data line DL and the edges CL-a of the corresponding common electrodes CL have at least a distance d′ therebetween. The distance d and the distance d′ are both greater than zero in this embodiment and preferably greater than the maximum error tolerance (e.g., 3 um) in an alignment process. Thereby, the storage capacitances of the pixels at the right and the left sides of the data line DL are not apt to be affected by the misalignment of the first metal layer 302 and the second metal layer 308. As such, the issues (e.g., non-uniform luminance, cross talk, and so on) of unfavorable display quality caused by the inconsistent storage capacitances at the right and the left sides of the data line DL can be resolved.

In light of the foregoing, the predetermined opening of the common electrode can prevent a portion of the second metal layer, a portion of the semiconductor layer, and a portion of the gate insulator that are located below the hole from being etched because of the uneven photoresist coating according to this invention. Further, the issue of the short circuit between the common electrode and the pixel electrode can be resolved.

Moreover, as long as the predetermined opening is properly located, the unfavorable display quality resulting from the misalignment of the first metal layer and the second metal layer can be improved.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A pixel structure comprising:
a substrate;
a first metal layer configured on the substrate and comprising:
a scan line;
a gate electrically connected to the scan line;
a common electrode separated from the scan line and having a predetermined opening, the predetermined opening located on an edge of the common electrode;
a gate insulator configured on the substrate and covering the first metal layer;
a semiconductor layer configured on the gate insulator;
a second metal layer configured on the semiconductor layer, the semiconductor layer underlying the entire second metal layer, the second metal layer comprising:
a data line intersecting the scan line;
a source electrically connected to the data line;
a drain;
a storage electrode located above the predetermined opening;
a passivation layer configured on the substrate and covering the second metal layer, the passivation layer having an opening exposing the drain;
a hole located in the predetermined opening, going through the passivation layer, and exposing the second metal layer; and
a pixel electrode configured on the passivation layer and filling the hole, the pixel electrode electrically connected to the drain via the opening and electrically connected to the second metal layer via the hole.

2. The pixel structure as claimed in claim 1, wherein the hole going through the passivation layer and located in the predetermined opening does not go through the second metal layer, the semiconductor layer, and the gate insulator.

3. The pixel structure as claimed in claim 1, wherein the hole going through the passivation layer and located in the predetermined opening further goes through the second metal layer, the semiconductor layer, and the gate insulator and exposes a side wall of the second metal layer, a side wall of the semiconductor layer, a side wall of the gate insulator, and a surface of the substrate.

4. The pixel structure as claimed in claim 1, wherein the common electrode is located at peripheries of the pixel electrode and partially overlapped with the pixel electrode.

5. The pixel structure as claimed in claim 4, wherein the overlapping portion of the common electrode and the pixel electrode is where a storage capacitor is formed.

6. The pixel structure as claimed in claim 1, wherein an overlapping portion of the common electrode and the storage electrode is where a storage capacitor is formed.

7. The pixel structure as claimed in claim 1, wherein the common electrode has at least one bending portion, and the predetermined opening and the at least one bending portion at least have a distance therebetween.

8. The pixel structure as claimed in claim 1, wherein the predetermined opening and an edge of the storage electrode at least have a distance therebetween.

9. The pixel structure as claimed in claim 1, wherein the hole is substantially smaller than the predetermined opening.

10. A dual gate pixel structure comprising:
a substrate;
a first metal layer configured on the substrate and comprising:
two scan lines;
two gates electrically connected to the scan lines, respectively;
a common electrode separated from the scan lines and having two predetermined openings located on an edge of the common electrode;
a gate insulator configured on the substrate and covering the first metal layer;
a semiconductor layer configured on the gate insulator;
a second metal layer configured on the semiconductor layer, the semiconductor layer underlying the entire second metal layer, the second metal layer comprising:
a data line intersecting the scan lines;
two sources electrically connected to the data line, respectively;
two drains;
two storage electrodes, each of the two storage electrodes located above one of the predetermined openings corresponding thereto;
a passivation layer configured on the substrate and covering the second metal layer, the passivation layer having two openings to expose the drains;
two holes respectively located in the predetermined openings, going through the passivation layer, and exposing the second metal layer; and
two pixel electrodes configured on the passivation layer and respectively filling the holes, the pixel electrodes electrically connected to the drains via the openings and electrically connected to the second metal layer via the holes, respectively.

11. The dual gate pixel structure as claimed in claim 10, wherein the holes going through the passivation layer and located in the predetermined openings do not go through the second metal layer, the semiconductor layer, and the gate insulator.

12. The dual gate pixel structure as claimed in claim 10, wherein the holes going through the passivation layer and located in the predetermined openings further go through the second metal layer, the semiconductor layer, and the gate insulator and expose a side wall of the second metal layer, a side wall of the semiconductor layer, a side wall of the gate insulator, and a surface of the substrate.

13. The dual gate pixel structure as claimed in claim 10, wherein the common electrode is located at peripheries of the pixel electrodes and partially overlapped with the pixel electrodes.

14. The dual gate pixel structure as claimed in claim 13, wherein the overlapping portion of the common electrode and the pixel electrodes is where a storage capacitor is formed.

15. The dual gate pixel structure as claimed in claim 10, wherein an overlapping portion of the common electrode and the storage electrodes is where a storage capacitor is formed.

16. The dual gate pixel structure as claimed in claim 10, wherein the common electrode has at least one bending portion, and the predetermined openings and the at least one bending portion at least have a distance therebetween.

17. The dual gate pixel structure as claimed in claim 10, wherein the predetermined openings and an edge of the storage electrodes corresponding thereto at least have a distance therebetween.

18. The dual gate pixel structure as claimed in claim 10, wherein the holes are substantially smaller than the predetermined openings.
